(19) United States
(12) Patent Application Publication
(10) Pub. No.: US 2013/0255721 A1
(43) Pub. Date: Oct. 3, 2013

(54) CONCAVE NODULE SPONGE BRUSH

(71) Applicant: ILLINOIS TOOL WORKS INC., Glenview, IL (US)

(72) Inventors: Jeffrey J. Tyrrell, West Berlin, NJ (US); Bradley S. Withers, El Dorado Hills, CA (US)

(73) Assignee: ILLINOIS TOOL WORKS INC., Glenview, IL (US)

(21) Appl. No.: 13/804,428

(22) Filed: Mar. 14, 2013

Related U.S. Application Data
(60) Provisional application No. 61/619,525, filed on Apr. 3, 2012.

(51) Int. Cl. H01L 21/02

(52) U.S. Cl. CPC H01L 21/02096
USPC 134/6; 15/179

(57) ABSTRACT

Cleaning devices and methods for cleaning substrates are provided. In one aspect, a cleaning device for cleaning a substrate includes a brush including an outer surface and defines a hollow bore positioned around a central axis of the brush, and nodules formed on the outer surface of the brush and each nodule includes a concave surface. Each concave surface defines an outer edge surrounding a central concavity point. In another aspect, a method for cleaning a substrate includes engaging a substrate with a cleaning device. The cleaning device includes a brush including an outer surface and defines a hollow bore positioned around a first axis of the brush, and nodules formed on the outer surface and each nodule includes a concave surface. Each concave surface defines an outer edge surrounding a central concavity point. The method also includes rotating the brush about the first axis in a first rotational direction.

### RELATED APPLICATIONS

The present application claims the benefit of co-pending U.S. Provisional Patent Application No. 61/619,525, filed Apr. 3, 2012, the entire contents of which is incorporated herein by reference.

### FIELD OF THE INVENTION

The present disclosure relates generally to processes and devices for cleaning articles. More specifically, it relates to a brush used for cleaning semiconductor substrates.

### BACKGROUND

Cast cylindrical polyvinyl alcohol brushes, also known as cleaning brushes, are conventionally used in automatic cleaning systems to provide a post CMP (Chemical Mechanical Planarization) process to effectively clean surfaces of substrates such as semiconductor wafers or other disc-shaped substrates. Cleaning brushes are also used in cleaning systems to clean and dry glass and other non-disc-shaped substrates in flat panel display manufacture, glass production, and printed circuit board assembly. Cleaning brushes may have a length as short as 50 millimeters or as long as 10 meters, for example.

The cleaning brushes are located on and driven by a central brush core in the cleaning process. An accurate and stable connection between the cleaning brush and the central brush core is desirable.

The cleaning brushes are expected to accurately rotate on their axis and provide a generally cylindrical surface with a generally consistent nodule pressure pattern over their useful life, which defines optimum cleaning of the entire substrate surface in the least amount of time with minimal damage to the substrate surface. In some cases, the cleaning brush is formed around the central brush core. For example, the brush core may be placed in a mold and a mixture of chemicals, such as polyvinyl alcohol, is injected into the mold to form the cleaning brush around the central brush core.

When a rotating cleaning brush engages a substrate, such as a semiconductor wafer, particles may get trapped between the cleaning brush and the substrate due to the normal force applied onto the substrate from the cleaning brush. Particles trapped between the cleaning brush and the substrate may scratch the substrate. Additionally, the normal force applied onto the substrate results in increased pressure between the cleaning brush and the substrate which slows down the rotational velocity of the cleaning brush against the substrate. As a result of the reduced rotational velocity, additional time is required in order to clean the substrate.

As a result, it would be desirable to have a cleaning brush in which less particles may get trapped between the cleaning brush and the substrate. Additionally, it would be desirable to have a cleaning brush in which the normal force applied onto the substrate from the cleaning brush is reduced, resulting in reduced pressure between the cleaning brush and the substrate and increased rotational velocity of the cleaning brush against the substrate.

### SUMMARY

In one aspect, a cleaning device for cleaning substrates is provided. The cleaning device includes, but is not limited to, a cleaning brush and a plurality of concave nodules. The cleaning brush has an outer cleaning surface surrounding a hollow bore and positioned around a central axis a₁. The plurality of concave nodules are formed on the outer cleaning surface and positioned about the central axis a₁. Each concave nodule has a concave outer surface. Each concave outer surface defines an outer edge surrounding a central concavity point P₁.

In another aspect, a method for cleaning substrates is provided. The method includes, but is not limited to, engaging a substrate with a cleaning device. The cleaning device includes a cleaning brush having an outer cleaning surface surrounding a hollow bore and positioned around a first central axis a₁, and a plurality of concave nodules formed on the outer cleaning surface and positioned about the first central axis a₁. Each concave nodule has a concave outer surface. Each concave outer surface defines an outer edge surrounding a central concavity point P₁. The method also includes, but is not limited to, rotating the brush about the first central axis a₁ in a first rotational direction α.

In a further aspect, a cleaning device for cleaning substrates is provided. The cleaning device includes, but is not limited to, a cleaning brush having an outer cleaning surface surrounding a hollow bore and positioned around a central axis a₁. The cleaning devices also includes, but is not limited to, a plurality of concave nodules formed on the outer cleaning surface and positioned about the central axis a₁. Each concave nodule has a concave outer surface which curves inwards towards the central axis a₁.

In still another aspect, a cleaning device for cleaning a substrate is provided and includes a brush including an outer surface and defining a hollow bore therein positioned around a central axis of the brush. The cleaning device also includes a plurality of nodules formed on the outer surface of the brush and each nodule includes a concave surface. Each concave surface defines an outer edge surrounding a central concavity point.

In still a further aspect, a method for cleaning a substrate is provided and includes engaging a substrate with a cleaning device. The cleaning device includes a brush including an outer surface and defining a hollow bore therein positioned around a first axis of the brush. The cleaning device also includes a plurality of nodules formed on the outer surface and each nodule includes a concave surface. Each concave surface defines an outer edge surrounding a central concavity point. The method further includes rotating the brush about the first axis in a first rotational direction.

In yet another aspect, a cleaning device for cleaning a substrate is provided and includes a brush including an outer surface and defining a hollow bore therein positioned around a central axis of the brush. The cleaning device also includes a plurality of nodules formed on the outer surface and each nodule includes a concave surface that curves inwards towards the central axis.

The scope of the present disclosure is defined solely by the appended claims and is not affected by the statements within this Summary.

### BRIEF DESCRIPTION OF THE DRAWINGS

The disclosure can be better understood with reference to the following drawings and description. The components in the figures are not necessarily to scale, emphasis instead being placed upon illustrating the principles of the disclosure.

FIG. 1 depicts a perspective view of an exemplary cleaning system for cleaning and polishing substrates, this exemplary cleaning system includes a cleaning device illustrated in FIG. 2, in accordance with one embodiment of the present disclosure.

FIG. 2 depicts a perspective view of the exemplary cleaning device illustrated in FIG. 1 including a cleaning brush and brush core with a plurality of nodules positioned on the cleaning brush, each of the plurality of nodules includes a concave surface, in accordance with one embodiment of the present disclosure.

FIG. 3 depicts a partially exploded perspective view of another exemplary cleaning device including a cleaning brush having nodules and a brush core, each of the plurality of nodules includes a concave surface, in accordance with one embodiment of the present disclosure.

FIG. 4 depicts a side view of the cleaning brush illustrated in FIGS. 1 and 2, in accordance with one embodiment of the present disclosure.

FIG. 5 depicts a cross-sectional view taken along line 5-5 of the cleaning brush illustrated in FIG. 2, in accordance with one embodiment of the present disclosure.

FIG. 6 depicts a first end view of the cleaning brush depicted in FIG. 4, in accordance with one embodiment of the present disclosure.

FIG. 7 depicts a perspective view of the cleaning brush depicted in FIG. 4, in accordance with one embodiment of the present disclosure.

FIG. 8 depicts a second end view of the cleaning brush depicted in FIG. 4, in accordance with one embodiment of the present disclosure.

FIG. 9 depicts a second cross-sectional view taken along line C-C in FIG. 4, in accordance with one embodiment of the present disclosure.

FIG. 10 is an enlarged view of a portion of the cleaning brush depicted in FIG. 6, in accordance with one embodiment of the present disclosure.

FIG. 11 depicts an enlarged cross-sectional side view of a portion of a cleaning brush including an exemplary concave nodule, in accordance with one embodiment of the present disclosure.

FIG. 12 depicts an enlarged cross-sectional side view of a portion of a cleaning brush including another exemplary concave nodule, in accordance with one embodiment of the present disclosure.

FIG. 13 depicts an enlarged cross-sectional side view of a portion of a cleaning brush including an exemplary concave nodule engaging a substrate, in accordance with one embodiment of the present disclosure.

### DETAILED DESCRIPTION

Methods and systems consistent with the present disclosure overcome the disadvantages of conventional brushes and brush-core systems by forming a cleaning brush including concave nodules, resulting in less pressure between the cleaning brush and the substrate being cleaned at an engagement area along which the cleaning brush engages the substrate.

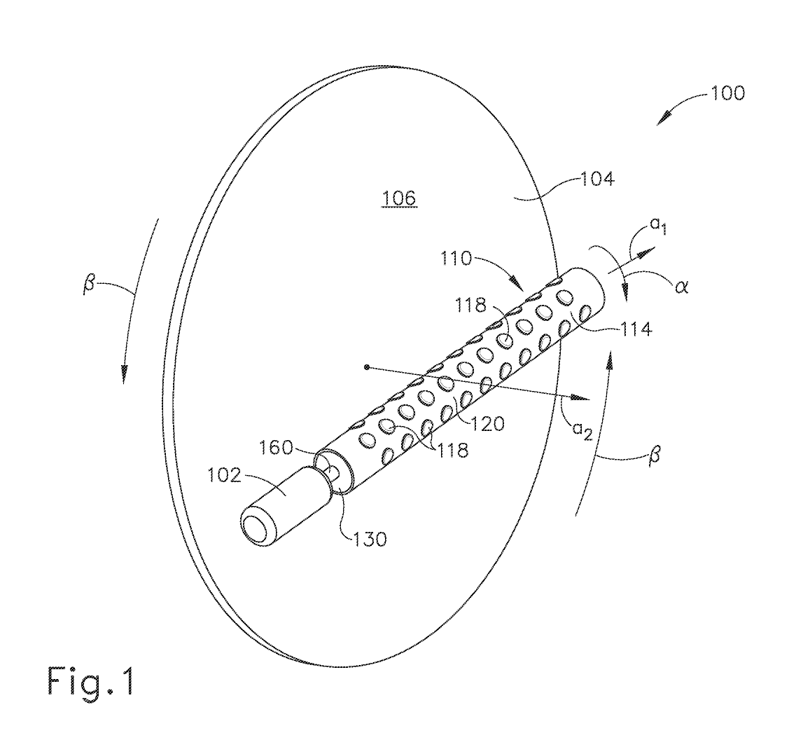

With reference to FIG. 1, there is shown a cleaning system 100 for cleaning and polishing substrates 104. The cleaning system 100 may be an automatic cleaning system which can automatically or manually be set to polish and/or clean a substrate 104, and more particularly a surface 106 of the substrate 104. Substrate 104 may be any one of a variety of circular, disc-shaped or non-disc-shaped substrates, such as: silicon based substrates including glass, dry glass, semiconductor wafers, flat panel display glass panels, glass production panels, and printed circuit boards; polymer-based substrates; and various types of semiconductor substrates such as silicon-based semiconductor substrates, single element semiconductor substrates, silicon on insulator (SOI) substrates, III-V semiconductor substrates, II-VI semiconductor substrates, other binary semiconductor substrates, ternary semiconductor substrates, quaternary semiconductor substrates; fiber optic substrates; superconducting substrates; glass substrates; fused quartz substrates; fused silica substrates; epitaxial silicon substrates; and organic semiconductor substrates.

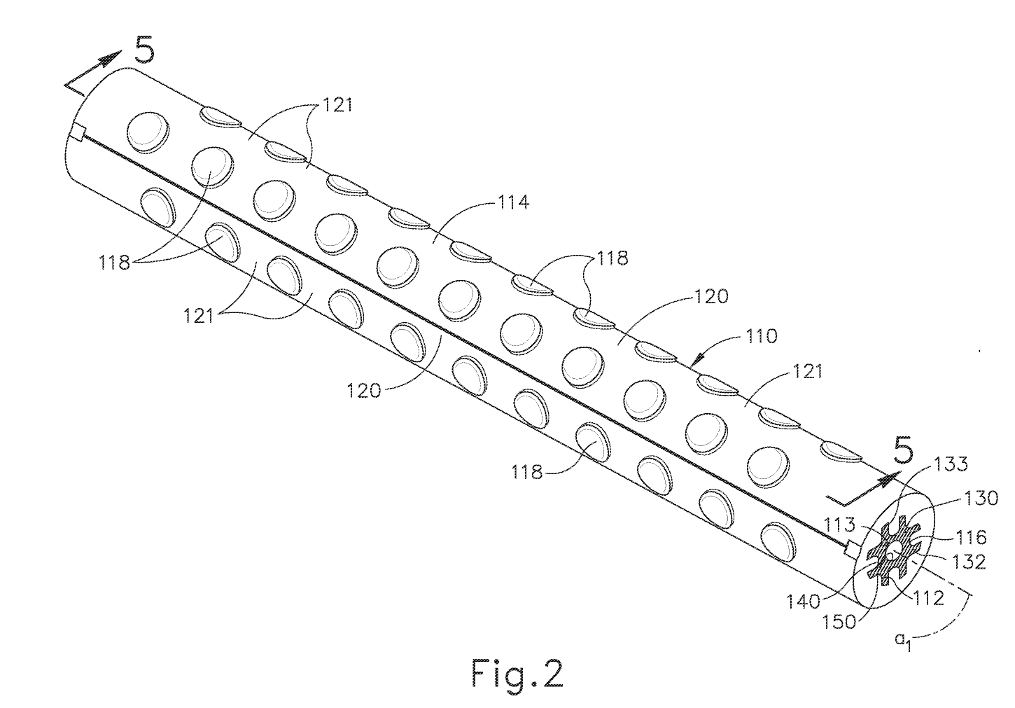

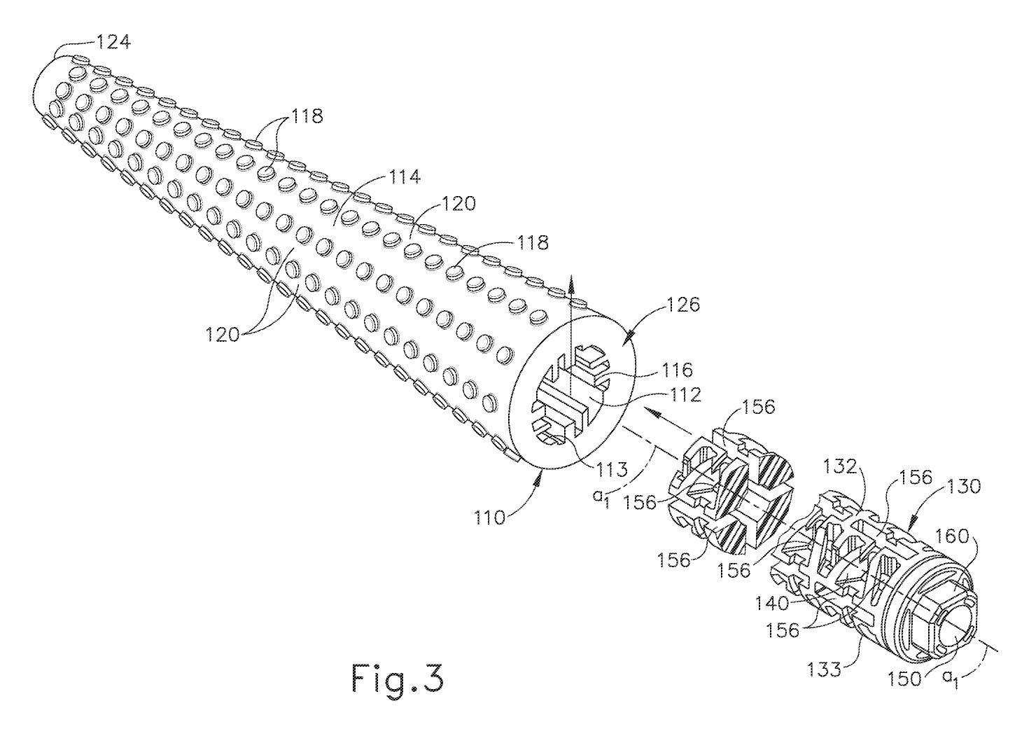

With reference to FIGS. 1 and 2, a first exemplary embodiment of a cleaning brush 110 and brush core 130 is illustrated. With reference to FIG. 3, a second exemplary embodiment of a cleaning brush 110 and brush core 130 is illustrated. It should be understood that the cleaning system 100 of the present disclosure is capable of utilizing a wide variety of cleaning brushes and various exemplary brushes will be described and referred to herein. The exemplary cleaning brushes described and illustrated herein are not intended to be limiting on the present disclosure. Moreover, it should be understood that the cleaning system 100 of the present disclosure is capable of utilizing a wide variety of cores with the cleaning brushes and various exemplary cores will be described and referred to herein. The exemplary cores described and illustrated herein are not intended to be limiting on the present disclosure.

With reference to FIGS. 1-3, cleaning system 100 includes a cleaning brush 110 having a hollow bore 112, a brush core 130 engaging the brush 110 within the hollow bore 112, and a rotational device 102 engaging the brush core 130. The cleaning brush 110 may be utilized in an automatic cleaning system to provide a post chemical mechanical planarization (CMP) process to effectively clean the surface 106 of substrate 104. The cleaning brush 110 may be made of a variety of different materials including, but not limited to, a cast polyvinyl alcohol (PVA) foam, a polyurethane foam, other polymeric foam, or a wide variety of other absorbent materials capable of satisfactorily cleaning and/or polishing a surface 106 of a substrate 104. The cleaning brush 110 may be a wide variety of shapes such as, for example, generally frusto-conically shaped, conically-shaped, or cylindrically-shaped.

As defined herein, a generally conically-shaped member, or a generally frusto-conically shaped member, such as the brush 110 illustrated in FIG. 3, is a member which is formed around a longitudinal central axis a₁ and may be balanced around the central axis a₁ in such a way that the centrifugal forces generated by the member as the member rotates around the central axis a₁ vary by no more than about ±20%. This configuration provides for a relatively balanced member where one end 126 has a greater cross sectional area, when taken perpendicular to the central axis a₁, than a second end 124. As a result, a generally conically-shaped member or a generally frusto-conically shaped member is provided. Such a member may not have a perfectly smooth outer surface, but can have interruptions, such as nodules, projections, or cavities formed on or in its outer surface.

With respect to FIGS. 1 and 2, a generally cylindrically-shaped member, such as the brush 110, is a member which is formed around a longitudinal central axis a₁, and which may be balanced around the central axis a₁ in such a way that the centrifugal forces generated by the member as the member rotates around the central axis a₁ vary by no more than ±20%, providing for a relatively balanced brush 110. As a result, the brush 110 does not have to have a perfectly cylindrical outer surface 110, but can have interruptions, such as nodules, projections, or cavities formed on or in its outer surface 114.

With reference to FIG. 3, the cleaning brush 110 includes an outer cleaning surface 114 opposed to an inner surface 113, forming the hollow bore 112. The hollow bore 112 may be formed around the brush core 130 by, for example, injection molding the brush 110 around an already formed brush core 130 or the hollow bore 112 may be formed and then later placed around the brush core 130. The hollow bore 112 is defined by the inner surface 113 of the conically-shaped brush 110. In one embodiment, the inner surface 113 is interrupted by a second engagement member 116 which mates with and surrounds a first engagement member 140 of the brush core 130. By forming the second engagement member 116 around the first engagement member 140, the brush 110 is securely fitted to the brush core 130 in order to prevent slippage and movement between the brush core 130 and the brush 110.

With reference to FIG. 2, the brush core 130 engages the brush 110 within the hollow bore 112. The brush core 130 includes a body section 132 which forms an outer surface 133 which engages and is secured to the inner surface 113 defining the hollow bore 112 of the brush 110. In this illustrated exemplary embodiment, the brush core 130 is generally cylindrically shaped.

With continued reference to FIG. 2, outer surfaces 114 and 133 may be positioned about a central axis a₁ of the brush core 130, or the outer surfaces 114 and 133 may be positioned symmetrically about the central axis a₁ of the brush core 130. In order to prevent rotational movement, and also axial movement, between the brush 110 and the brush core 130, the profile or contour of the outer surface 133 may be interrupted by a first engagement member 140. Rotational movement is defined herein as movement along a rotational direction α about the central axis a₁, as shown in FIG. 1. Axial movement is defined herein as movement along an axial direction which is generally perpendicular to, within about ±30° of, the central axis a₁. First engagement member 140 is any feature which interrupts the general contour of outer surface 133 in order to better engage the second engagement member 116 of the brush 110. First engagement member 140 includes such features as a band or a series of bands, a ridge or series of ridges, or a channel or a series of channels at any number of locations along the outer surface 133 to effectively axially secure the brush 110 to the brush core 130.

As a result of first and second engagement members 140, 116, the physical fit between the outer surface 133 of the brush core 130 and the inner surface 113 of the brush 110 provides significant resistance to slipping. This resistance to slipping could be further enhanced by other methods including adhesives, surface preparation of the core (chemical, physical, corona, and the like), or such additional surface features as knurls, sharp edges, hooks, points, keys, or other linking features.

With reference to FIG. 3, pores 156 are formed from the outer surface 133 of the body section 132 to a fluid channel 150 in the body section 132 for flowing cleaning and/or polishing fluid from the fluid channel 150 to the outer surface 133 of the body section 132 and to the brush 110.

With reference to FIGS. 1 and 3, in one embodiment, the brush core 130 also includes a rotational engagement member 160 for engaging and connecting with a rotational device 102. The rotational engagement member 160 is any device which can be used to connect with or fasten to another device, and includes things such as, for example, a nut-shaped piece or any other polygonal perimetered piece that is unitarily formed as one-piece with the brush core 130 and can be fastened to the rotational device 102. The rotational device 102 includes any device which can induce a rotational movement onto the brush core 130, such as an electrical motor, a gas motor or engine, a crank shaft power by a motor or manually powered, and any combination of pulleys, wheels, mechanical linkages, and/or gears moved automatically or manually. The rotational device 102 has a complimentary engagement member which connects with the rotational engagement member 160 for engaging and connecting the brush core 130 with the rotational device 102.

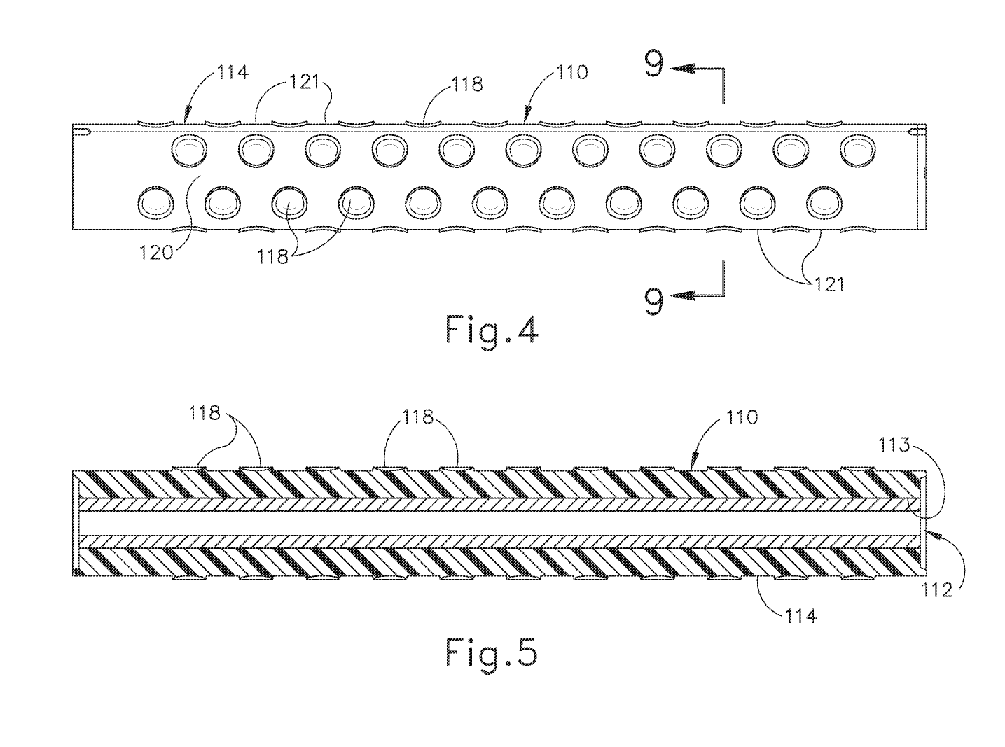

With reference to FIGS. 1-4, outer cleaning surface 114 includes exemplary nodules 118 formed on or in the outer cleaning surface 114 and having channels 120 or ridges 121 formed between the nodules 118. Having surface features such as nodules 118 with channels 120 or ridges 121 may help brush 110 to better clean certain substrates 104. Surface features on the outer cleaning surface 114, such as cavities, channels 120, lines, edges, points, or nodules 118, may be incorporated and have a beneficial effect at increasing torque transmission levels, but may be limited due to their effect on outer cleaning surface 114 geometry changes.

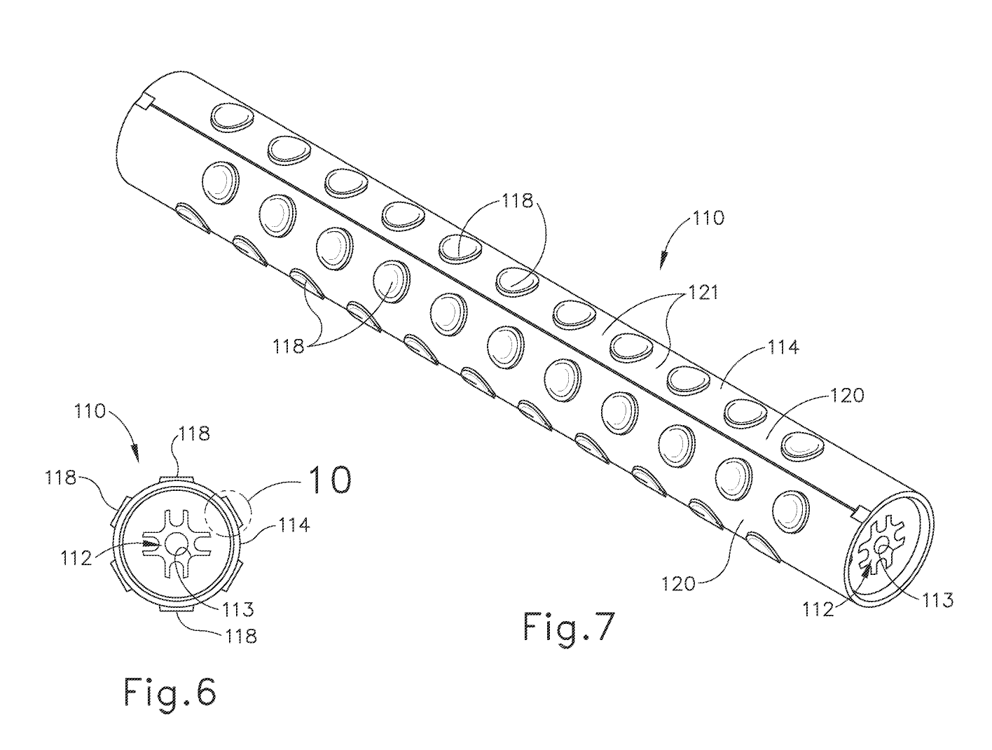

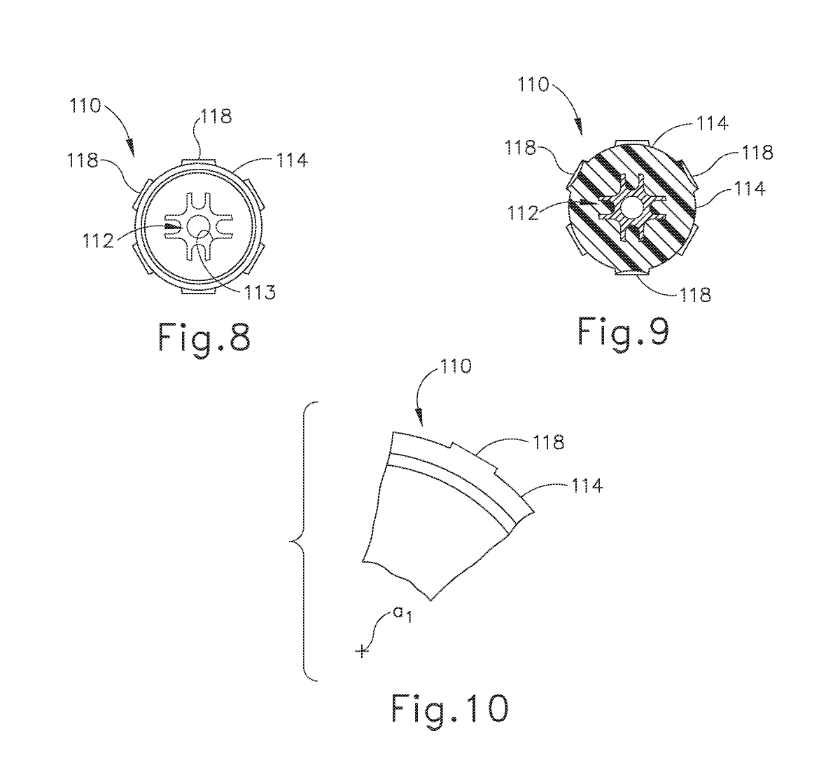

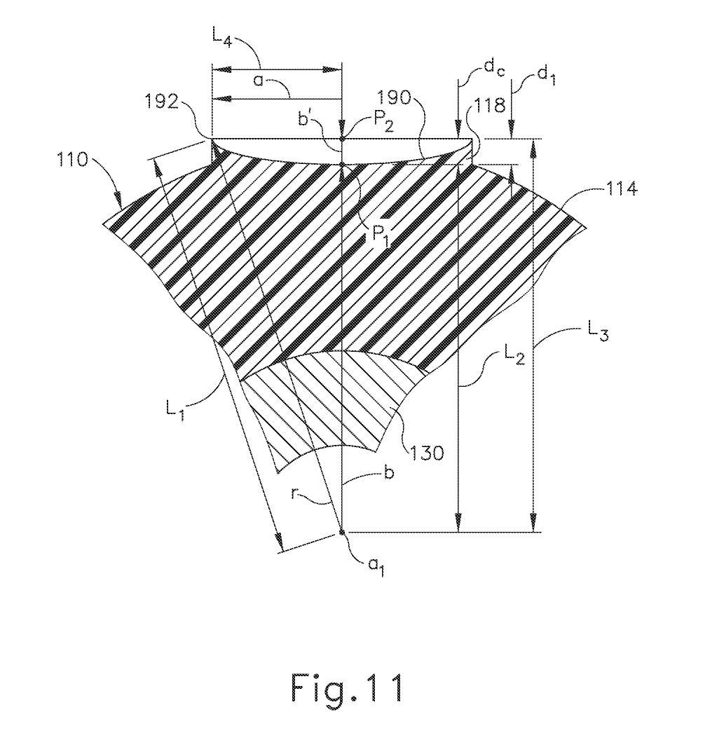

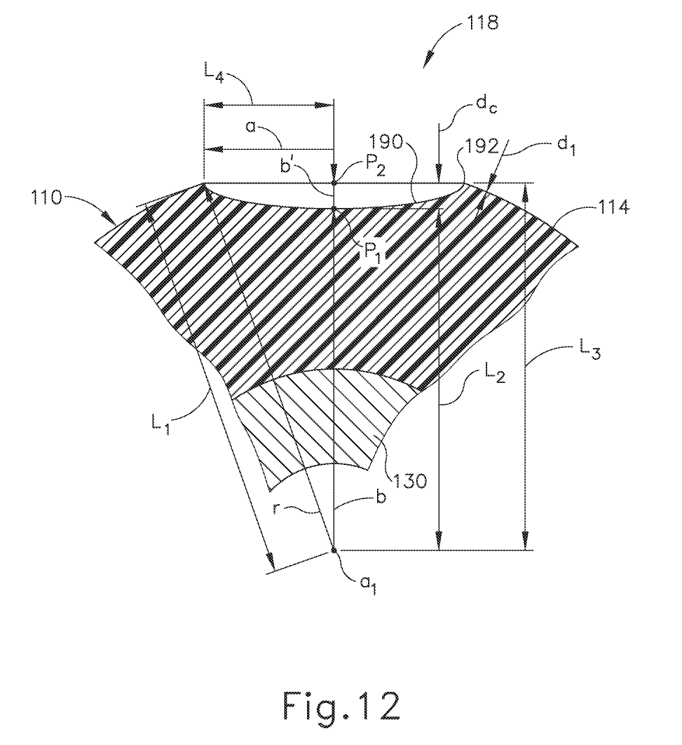

With reference to FIGS. 1-12, nodules 118 are concave nodules 118 formed on the outer cleaning surface 114 and positioned about the central axis a₁. Each concave nodule 118 has a concave outer surface 190 and each concave outer surface 190 defines an outer edge 192 surrounding a central concavity point P₁. Concave nodules 118 each have an outline or surface 190 that curves inward like the interior of a circle or sphere or spheroid. When traveling along the concave outer surface 190, from the outer edge 192 to the central concavity point P₁, the concave outer surface 190 curves inwards towards the central axis a₁, as shown in FIGS. 11 and 12. Concave nodules 118 formed on the outer cleaning surface 114 of the cleaning brush 110 result in less pressure between the cleaning brush 110 and the substrate 104 being cleaned at an engagement area along which the outer cleaning surface 114 of the cleaning brush 110 engages the surface 106 of the substrate 104. In some embodiments, concave modules 118 also result in less contact area between the nodules 118 and the surface 106 of the substrate 104 because the outer edge 192 and, possibly, only a portion of the concave surface 190 engage the substrate 104 while at least a portion of the concave surface 190 does not engage the substrate 104.

In one embodiment, with reference to FIG. 11, concave nodules 118 project a first distance d₁ above the outer cleaning surface 114. The outer edge 192 of the concave nodules 118 are formed a distance d₁ above the outer cleaning surface 114. The distance d₁ is from about 0.5 mm to about 10 mm. In other embodiments, the distance d₁ is less than 0.5 mm, and actually about 0 mm 0.5 mm, as shown in FIG. 12. In such embodiments, the concave nodules 118 may be formed flush with the outer cleaning surface 114. In further embodiments, the outer edge 192 of the concave nodule 118 may be formed underneath or internal of the outer cleaning surface 114 and the distance d₁ is less than 0 mm, such as from −0.5 mm to −10 mm from and below the outer cleaning surface 114.

With reference to FIGS. 11 and 12, the central concavity point P₁ is at or near a center of the concave outer surface 190. The central concavity point P₁ is within ±5 mm of a center of the concave outer surface 190. The center of the concave outer surface 190 may be a point on the concave outer surface 190 which is closest to the central axis a₁. A first brush radius r extends from the central axis a₁ to the outer edge 192 and has a first length L₁. A second brush radius b extends from the central axis a₁ to the central concavity point P₁ and has a second length L₂. The first brush radius r is greater than the second brush radius b. A third brush radius b′, projecting in a direction parallel to the second radius b, extends from the central axis a₁ to a central point P₂ above the central concavity point P₁. The third brush radius b′ has a third length L₃ which is greater than the second length L₂. A nodule radius “a” extends from the outer edge 192 in a direction perpendicular to the third brush radius b′ and towards the central point P₂. The nodule radius “a” intersects the third brush radius b′, at a right angle about ±5°, at the central point P₂. A difference between the third length L₃ and the second length L₂ is equal to a concavity depth d_{c} of the concave nodule 118.

In one embodiment, the nodule radius “a” has a fourth length L₄ which is equal to a square root of (L₁²−L₃²). The concavity depth d_{c} may be from about 1/50 to about ½ the fourth length L₄, or may be from about 1/40 to about ¼ the fourth length L₄. In another embodiment, the concavity depth d_{c} is from about 0.1 mm to about 5 mm in length. By forming the concavity depth to have a length from about 1/50 to about ½ the fourth length L₄, the concave nodule 118 results in less pressure between the cleaning brush 110 and the substrate 104 being cleaned at an engagement area along which the cleaning brush 110 engages the substrate 104.

The illustrated exemplary nodules illustrated and described herein are merely examples of the many different types, sizes, and configurations of nodules and are not intended to be limiting upon the present disclosure. All of such nodule possibilities are intended to be within the spirit and scope of the present disclosure. For example, the nodules may have any size diameter, may be shapes other than circular such as oblong, oval, rhombus with rounded corners, or any polygonal or arcuately perimetered shape. In some cases, the concavity of the nodule increases as the diameter or size of the nodule increases, thereby providing a deeper concave surface to the nodule. Moreover, the nodules may be oriented on the outer surface of the brush in any manner and all of such possibilities are intended to be within the spirit and scope of the present invention. For example, the brush may include a different density of nodules on its outer surface, the nodules may not be aligned in straight lines, etc.

In operation, the brush 110 may be placed or formed around the brush core 130 by injection molding the brush 110 around the brush core 130. Upon placing or forming the brush 110 around the brush core 130, the brush core 130 and the brush 110 are then connected with the rotational device 102 by connecting the rotational engagement member 160 with an engagement member on the rotational device 102. Then, the brush 110 is rotated along the rotational direction α about the central axis a₁. While rotating the brush 110, or before rotating the brush 110, the brush 110 is placed near and engages the surface 106 of the substrate 104.

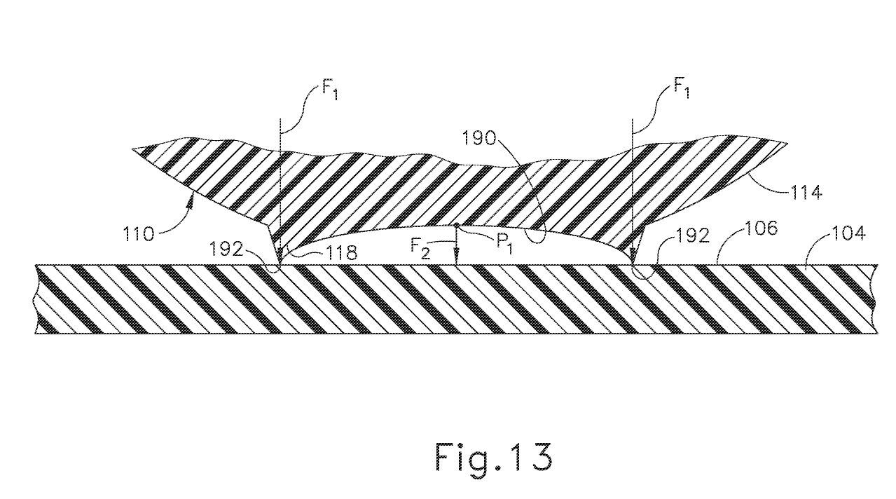

The brush 110 engages the substrate 104 with the brush core 130 positioned about a first central axis a₁. Upon engaging the brush 110 with the substrate 104, the brush is then rotated about the first central axis a₁ in a first rotational direction α and the substrate 104 is rotated about a second central axis a₂ in a second rotational direction β. The second central axis a₂ is either perpendicular to or intersects the first central axis a₁. With reference to FIG. 13, the outer edge 192 of the concave nodule 118 engages the substrate 104 with a first force F₁ normal to the substrate 104 and the central concavity point P₁ of the concave nodule 118 engages the substrate 104 with a second force F₂ normal to the substrate 104 which is less than the first force F₁ as demonstrated by the different in lengths of the F₁ and F₂ arrows. In other embodiments, the outer edge 192 of the nodule 118 engages the substrate 104 and the central concavity point P does not engage the substrate 104.

The rotational motion of the brush 110 on the surface 106 helps to clean and/or polish the surface 106. With reference to FIG. 1, in one embodiment, the substrate 104 is also rotated along a rotational direction β about a second central axis a₂. In one embodiment, polishing fluid is pumped through fluid channel 150 formed in the body section 132 and into the brush 110 through pores 156 formed through the outer surface 133 of the body section 132 and to the fluid channel 150. The polishing fluid helps to further clean and/or polish the substrate 104. Providing for a brush 110 having a plurality of concave nodules 118 formed on the outer cleaning surface 114 results in less pressure and less surface contract between the cleaning brush 110 and the substrate 104 being cleaned at an engagement area along which the cleaning brush 110 engages the substrate 104.

Although the illustrative examples above describe PVA brushes 110 used to clean semiconductor substrates 104, one having skill in the art will appreciate that methods and systems consistent with the present disclosure are not limited thereto. For example, the brush 110 may include other materials and may be used to clean other types of surfaces 106 or substrates 104. Further, the brush 110 may or may not have nodules or cavities formed on or in the outer cleaning surface 114 of the brush 110.

In some embodiments, the concave surface 190 may actually be an absence of material in the cleaning surface 114 of the brush 110. In other words, a plurality of apertures may be defined through the surface 114 of the brush 110 all the way through to the bore 112. In such embodiments, the apertures are the nodules 118 and assist in cleaning and/or polishing the substrate 104. The apertures may similarly include an outer edge 192 and a central concavity point P and may function in the same manners and have similar benefits to other embodiments described herein. During manufacturing of such embodiments, the concavity of the apertures or nodules 118 defined in the brush 110 changes as the diameter of the apertures change.

The Abstract is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

While various embodiments of the disclosure have been described, it will be apparent to those of ordinary skill in the art that other embodiments and implementations are possible within the scope of the disclosure. Accordingly, the disclosure is not to be restricted except in light of the attached claims and their equivalents.

1. A cleaning device for cleaning a substrate, the cleaning device comprising:
a brush including an outer surface and defining a hollow bore therein positioned around a central axis of the brush; and
a plurality of nodules formed on the outer surface of the brush and each nodule includes a concave surface, and wherein each concave surface defines an outer edge surrounding a central concavity point.

2. The cleaning device of claim 1, wherein the outer edges of the nodules are formed flush with and do not project outwardly from the outer surface of the brush.

3. The cleaning device of claim 1, wherein the nodules project a distance outwardly from the outer surface.

4. The cleaning device of claim 1, wherein the central concavity point is one of at or near a center of the concave surface, wherein a first brush radius from the central axis to the outer edge of the concave surface has a first length, wherein a second brush radius from the central axis to the central concavity point has a second length, wherein a third brush radius projects from the central axis to a second point in a direction parallel to the second radius and has a third length greater than the second length, wherein a nodule radius extends from the outer edge of the concave surface in a direction which is perpendicular to the third brush radius and intersects the third brush radius at the second point, and wherein a difference between the third length and the second length is equal to a concavity depth of each nodule.

5. The cleaning device of claim 4, wherein the nodule radius has a fourth length which is equal to a square root of (the first length²−the third length).

6. The cleaning device of claim 5, wherein the concavity depth is from about 1/50 to about ½ the fourth length.

7. The cleaning device of claim 5, wherein the concavity depth is from about 1/40 to about ¼ the fourth length.

8. The cleaning device of claim 1, wherein the brush is one of generally conically-shaped, generally frusto-conically shaped or generally cylindrically-shaped.

9. A method for cleaning a substrate, the method comprising:
engaging a substrate with a cleaning device, the cleaning device including
a brush including an outer surface and defining a hollow bore therein positioned around a first axis of the brush, and
a plurality of nodules formed on the outer surface and each nodule includes a concave surface, wherein each concave surface defines an outer edge surrounding a central concavity point; and
rotating the brush about the first axis in a first rotational direction.

10. The method of claim 9, wherein engaging the substrate further includes
engaging the substrate with the outer edge of the concave surface with a first force normal to the substrate, and
engaging the substrate with the central concavity point of the concave surface with a second force normal to the substrate, wherein the second force is less than the first force.

11. The method of claim 9, wherein the substrate is a circular substrate, the method further comprising rotating the substrate about a second axis.

12. The method of claim 11, wherein the substrate is a circular semiconductor wafer.

13. The method of claim 9, wherein the brush is a polyvinyl alcohol brush.

14. The method of claim 9, wherein the central concavity point is one of at or near a center of the concave surface, wherein a first brush radius from the first central axis to the outer edge of the concave surface has a first length, wherein a second brush radius from the first central axis to the central concavity point has a second length, wherein a third brush radius projects from the first central axis to a second point in a direction parallel to the second radius and has a third length greater than the second length, wherein a nodule radius extends from the outer edge of the concave surface in a direction which is perpendicular to the third brush radius and intersects the third brush radius at the second point, and wherein a difference between the third length and the second length is equal to a concavity depth of each nodule.

15. The method of claim 14, wherein the nodule radius has a fourth length which is equal to a square root of (the first length²−the third length²).

16. The method of claim 9, wherein the concavity depth is from about 1/50 to about ½ the fourth length.

17. A cleaning device for cleaning a substrate, the cleaning device comprising:
a brush including an outer surface and defining a hollow bore therein positioned around a central axis of the brush; and
a plurality of nodules formed on the outer surface and each nodule includes a concave surface that curves inwards towards the central axis.

18. The cleaning device of claim 17, wherein each concave surface defines an outer edge surrounding a central concavity point, wherein the central concavity point is one of at or near a center of the concave surface, wherein a first brush radius from the central axis to the outer edge has a first length, wherein a second brush radius from the central axis to the central concavity point has a second length, wherein a third brush radius projects from the central axis to a second point in a direction parallel to the second radius and has a third length greater than the second length, wherein a nodule radius extends from the outer edge of the concave surface in a direction which is perpendicular to the third brush radius and intersects the third brush radius at the second point, and wherein a difference between the third length and the second length is equal to a concavity depth of each nodule.

19. The cleaning device of claim 18, wherein the nodule radius has a fourth length which is equal to a square root of (the first length²−the third length²).

20. The cleaning device of claim 19, wherein the concavity depth is from about 1/50 to about ½ the fourth length.
